(19) United States
(12) Patent Application Publication
(10) Pub. No.: US 2018/0190630 A1
(43) Pub. Date: Jul. 5, 2018

(54) PACKAGE STRUCTURE OF OPTICAL MODULE

(71) Applicant: LINGSEN PRECISION INDUSTRIES, LTD., TAICHUNG CITY (TW)

(72) Inventors: Ming-Te TU, TAICHUNG CITY (TW); Ching-I LIN, TAICHUNG CITY (TW); Chih-Wei LEE, TAICHUNG CITY (TW)

(21) Appl. No.: 15/434,676

(22) Filed: Feb. 16, 2017

(30) Foreign Application Priority Data
Dec. 30, 2016 (TW) 105144097

(51) Int. Cl. H01L 25/16; H01L 31/0232; H01L 31/16

(52) U.S. Cl. CPC H01L 25/167; H01L 31/16; H01L 31/02327

(57) ABSTRACT

A package structure of an optical module includes a substrate, a light-emitting chip, a sensing chip, two packaging gel bodies, and a cover layer. The substrate has a bearing surface. The light-emitting chip is disposed on the bearing surface by a die attach film. The sensing chip is disposed on the bearing surface by another die attach film and separated from the light-emitting chip. The two packaging gel bodies cover the light-emitting chip and the sensing chip respectively. The cover layer is disposed on the bearing surface and the two packaging gel bodies and provided with a light-emitting hole located above the light-emitting chip and a light-receiving hole located above the sensing chip.

### BACKGROUND OF THE INVENTION

### 1. Field of the Invention

The present invention relates generally to package structures and more particularly, to a package structure of an optical module.

### 2. Description of the Related Art

The optical sensing module is applied very widely, such as in automatic machines and intelligent devices. An example of that is the smart phone. When the smart phone is taken close to the cheek of the user or put into the pocket, the optical sensing module disposed in the smart phone will shut down the screen of the phone for saving electricity or preventing the user from accidentally touching the screen. The theory is that the optical sensing module can emit a light source by a light-emitting chip, such as an LED chip; after being reflected by an exterior object, the light source can be received by a sensing chip of the optical sensing module and transformed into electronic signal for the subsequent processing.

The conventional optical sensing module is manufactured in a way that a light-emitting chip and a sensing chip are disposed on a substrate by a chip attach process, then two packaging gel bodies are formed by molding to cover the light-emitting chip and the sensing chip respectively, and at last a cover layer is formed above the packaging gel bodies by molding, so that the package structure is accomplished.

In the two times of molding of the aforesaid manufacturing process, the stress applied on the light-emitting chip and the sensing chip may affect the properties of the chips, lowering the stability of the chips or even making the chips lose efficiency. Therefore, the conventional optical sensing module still has drawbacks and needs improvements.

### SUMMARY OF THE INVENTION

Summarizing the above description, it is a primary objective of the present invention to provide a package structure of an optical module, which can lower the stress applied on the chips, thereby lowering the affection caused by the stress to the chips and improving the efficiency of the whole product.

The package structure of the optical module includes a substrate, a light-emitting chip, a sensing chip, two packaging gel bodies, and a cover layer. The substrate has a bearing surface. The light-emitting chip is disposed on the bearing surface by a die attach film. The sensing chip is disposed on the bearing surface by another die attach film and separated from the light-emitting chip. The two packaging gel bodies cover the light-emitting chip and the sensing chip respectively. The cover layer is disposed on the bearing surface and the two packaging gel bodies and provided with a light-emitting hole located above the light-emitting chip and a light-receiving hole located above the sensing chip.

Preferably, the packaging gel bodies and the cover layer are formed by molding.

As a result, when the packaging gel bodies and the cover layer are formed by molding, the die attach films can lower the stress applied on the light-emitting chip and the sensing chip by the molding process, thereby lowering the affection caused by the stress to the light-emitting chip and the sensing chip. Therefore, the package structure of the optical module of the present invention has the advantages that the structure thereof is stable and the product has relatively better efficiency.

The detailed structure and features of the present invention will be specified in the detailed description of the embodiments given hereinafter. However, those skilled in the art should understand that the detailed description and the specific embodiments instanced for the implementing of the invention are given for illustration only, not for limiting the scope of the invention.

### BRIEF DESCRIPTION OF THE DRAWINGS

FIG. 1 is a top view of a preferred embodiment of the present invention.

FIG. 2 is a sectional view taken along the line 2-2 in FIG. 1, showing the arrangement of inner components of a package structure.

### DETAILED DESCRIPTION OF THE INVENTION

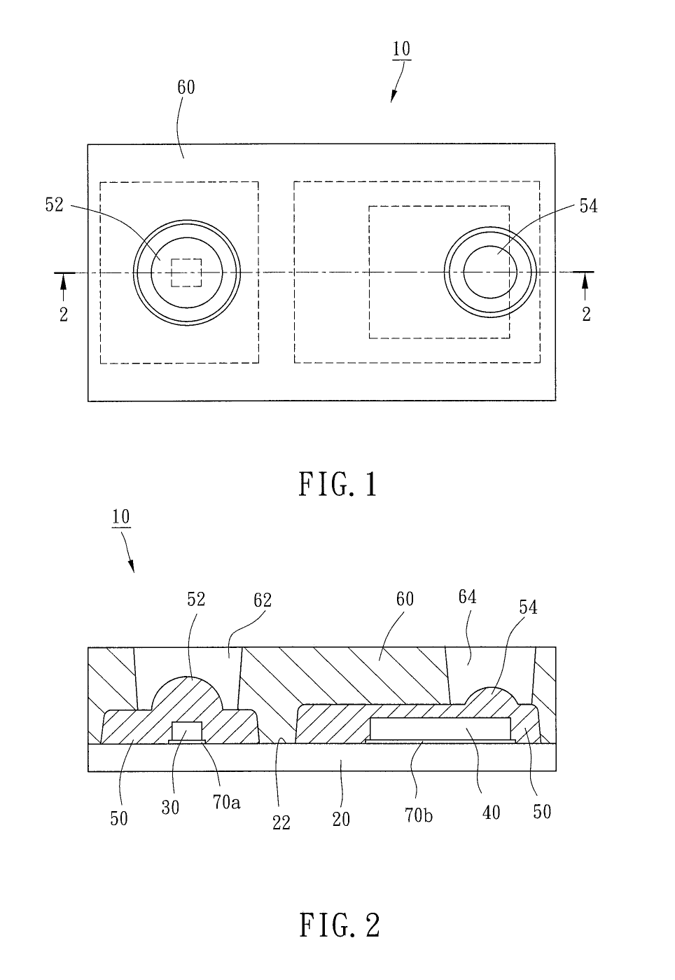

Referring to FIGS. 1-2, a package structure 10 of an optical module according to a preferred embodiment of the present invention includes a substrate 20, a light-emitting chip 30, a sensing chip 40, two packaging gel bodies 50, and a cover layer 60.

The substrate 20 in this preferred embodiment may, but unlimited to, be a bismaleimide-triazine (usually referred to as “BT”) substrate, a glass fiber substrate (usually referred to as “FR4”), or a direct bonded copper (usually referred to as “DBC”) substrate. In this way, the manufacturing cost of the substrate 20 is relatively lower. The substrate 20 has a bearing surface 22.

The light-emitting chip 30 is disposed on the bearing surface 22 by a die attach film 70a. In this preferred embodiment, the light-emitting chip 30 is an LED chip for emitting a light source.

The sensing chip 40 is disposed on the bearing surface 22 by a die attach film 70b and separated from the light-emitting chip 30. The sensing chip 40 is used for sensing the light source emitted by the light-emitting chip 30.

The two packaging gel bodies 50 in this preferred embodiment are made of a transparent material, such as transparent epoxy resin. The two packaging gel bodies 50 are formed by molding respectively and cover the light-emitting chip 30 and the sensing chip 40 respectively. It should be mentioned that the packaging gel bodies 50 are formed with a first lens portion 52 and a second lens portion 54, which are located above the light-emitting chip 30 and the sensing chip 40 respectively. The first lens portion 52 and the second lens portion 54 are hemisphere-shaped. In the manufacturing process, the radius of curvature of the first and second lens portions 52 and 54 can be modified according to requirements.

The cover layer 60 in this preferred embodiment is formed integrally and made of an opaque material, such as opaque epoxy resin. The cover layer 60 is formed by molding and disposed on the bearing surface 22 and the two packaging gel bodies 50. The cover layer 60 is provided with a light-emitting hole 62 and a light-receiving hole 64, which are located above the light-emitting chip 30 and the sensing chip 40 respectively. It should be mentioned that the first lens portion 52 and the second lens portion 54 are accommodated in the light-emitting hole 62 and the light-receiving hole 64 respectively.

The packaging process of the optical module provided by the present invention includes the following steps. The first step A is to provide the substrate 20 and dispose the light-emitting chip 30 and the sensing chip 40 on the bearing surface 22 of the substrate 20 by the die attach films 70a and 70b respectively. The second step B is to form the two packaging gel bodies 50 by molding to cover the light-emitting chip 30 and the sensing chip 40 respectively. At the same time, the packaging gel bodies 50 are formed with the first lens portion 52 and the second lens portion 54, which are located above the light-emitting chip 30 and the sensing chip 40 respectively. The third step C is to form the cover layer 60 integrally by molding in a way that the cover layer 60 is disposed on the bearing surface 22 and the two packaging gel bodies 50 and provided with the light-emitting hole 62 and the light-receiving hole 64, which are located above the light-emitting chip 30 and the sensing chip 40 respectively and accommodate the first lens portion 52 and the second lens portion 54 respectively.

In summary of the above description, the light-emitting chip 30 and the sensing chip 40 are disposed on the bearing surface 22 by the die attach films 70a and 70b respectively. When the packaging gel bodies 50 and the cover layer 60 are formed by two times of molding respectively, the die attach films 70a and 70b can lower the stress applied on the light-emitting chip 30 and the sensing chip 40 by the molding process, lowering the affection caused by the stress to the light-emitting chip 30 and the sensing chip 40, thereby improving the structural stability of the product and providing great efficiency.

At last, it should be mentioned again that the components disclosed in the above embodiments of the present invention are instanced for illustration only, not for limiting the scope of the invention. It will be obvious that the same may be varied and modified in many ways. Such variations and modifications are intended to be included within the scope of the following claims.

What is claimed is:

1. A package structure of an optical module, the package structure comprising:
a substrate having a bearing surface;
a light-emitting chip disposed on the bearing surface by a die attach film;
a sensing chip disposed on the bearing surface by another die attach film and separated from the light-emitting chip;
two packaging gel bodies covering the light-emitting chip and the sensing chip respectively; and
a cover layer disposed on the bearing surface and the two packaging gel bodies and provided with a light-emitting hole located above the light-emitting chip and a light-receiving hole located above the sensing chip.

2. The package structure as claimed in claim 1, wherein the packaging gel bodies and the cover layer are formed by molding.

3. The package structure as claimed in claim 1, wherein the packaging gel bodies are formed with a first lens portion and a second lens portion, which are located above the light-emitting chip and the sensing chip respectively.

4. The package structure as claimed in claim 3, wherein the first lens portion and the second lens portion are hemisphere-shaped.

5. The package structure as claimed in claim 3, wherein the first lens portion and the second lens portion are accommodated in the light-emitting hole and the light-receiving hole respectively.

6. The package structure as claimed in claim 1, wherein the packaging gel bodies are made of a transparent material; the cover layer is made of an opaque material.

7. The package structure as claimed in claim 1, wherein the cover layer is formed integrally.
